(19) United States
(12) Patent Application Publication
(10) Pub. No.: US 2026/0255694 A1
(43) Pub. Date: Aug. 27, 2026

(54) ANTISTATIC COATING AGENT, ANTISTATIC GLASS SUBSTRATE, AND SOLAR PANEL

(71) Applicants: SKETCH CO., LTD., Taito-ku, Tokyo (JP); SETSUDEN ECO SHOP CO., LTD., Taito-ku, Tokyo (JP)

(72) Inventors: Yasuhiro SHIMADA, Tokyo (JP); Hayato MINAMI, Tokyo (JP)

(21) Appl. No.: 18/861,038

(22) PCT Filed: May 17, 2023
(86) PCT No.: PCT/JP2023/018396

§ 371 Date: Oct. 28, 2024

(30) Foreign Application Priority Data
May 30, 2022 (JP) 2022-087435

(51) Int. Cl. H10F 19/80; B82Y 30/00; C03C 17/00; C09D 1/00; C09D 5/24; C09D 7/61

(52) U.S. Cl. CPC H10F 19/804; C03C 17/007; C09D 1/00; C09D 5/24; C09D 7/61; B82Y 30/00; C03C 2217/211; C03C 2217/213; C03C 2217/219; C03C 2217/28; C03C 2217/29

(57) ABSTRACT

There is provided an antistatic coating agent that is excellent in antistatic performance, hydrophilicity, and durability such as wear resistance and that makes it possible to form a coat layer having high visible light transmittance on a surface of a substrate made of glass easily at normal temperature, and an antistatic glass substrate using this antistatic coating agent. The antistatic coating agent is a normal-temperature-hardenable antistatic coating agent containing tin oxide (SnO₂), silica (SiO₂), tungsten oxide (WO₃), a single-walled carbon nanotube, and a liquid medium. The antistatic glass substate includes a substrate made of glass and a coat layer being a hardened layer provided on a surface of the substrate, the hardened layer formed from the antistatic coating agent.

### TECHNICAL FIELD

The present invention relates to an antistatic coating agent, an antistatic glass substrate, and a solar panel.

### BACKGROUND ART

Solar panels are configured by connecting plurality of solar cells (cells) to form a panel so that required power and current can be obtained. The solar panels are usually installed outdoors and therefore continuously exposed to wind and rain. Accordingly, a protective cover for protecting a solar panel is attached to the surface of a solar panel.

As a protective cover for protecting a solar panel, a substrate made of glass is usually used. Protective covers having an improved dirt-cleaning effect utilizing rainfall are used, wherein the improved dirt-cleaning effect is obtained by forming fine unevenness on the surface of such a substrate made of glass to enhance hydrophilicity. Note that more sunlight needs to be taken into solar cells during power generation, and therefore a protective cover having a high light transmittance needs to be used.

For example, as a related conventional technique, a transparent electrode-attached glass for solar cells has been proposed (Patent Literature 1), wherein a tin oxide layer or a titanium oxide layer, and an overcoat layer having a predetermined surface roughness are provided sequentially on a surface of a glass substrate, and dirt-cleaning performance is enhanced by improving hydrophilicity. However, when a substrate made of glass, wherein unevenness is provided on the surface thereof, is used for a solar panel to be installed in a region, such as a desert, where precipitation is small, there have been problems that dirt such as sand is more easily retained because of unevenness and that cleaning by rainfall is unlikely to be expected. Further, to produce a transparent electrode-attached glass proposed in Patent Literature 1, special factory facilities are needed, and therefore there has also been a problem that the transparent electrode-attached glass is lack of versatility.

On the other hand, a coating liquid in which tin oxide (SnO₂) and silica (SiO₂) are blended has been proposed (Patent Literatures 2 and 3). It is stated that according to the coating liquid proposed in Patent Literatures 2 and 3, by hardening, at normal temperature, the coating liquid after directly applying the coating liquid on a substrate made of glass, a coating film having properties such as antistatic performance can be formed.

### CITATION LIST

### Patent Literature

Patent Literature 1: Japanese Patent Laid-Open No. 2001-007363
Patent Literature 2: Japanese Patent Laid-Open No. 2013-080067
Patent Literature 3: Japanese Patent Laid-Open No. 2013-130593

### SUMMARY OF INVENTION

### Technical Problem

According to the coating liquid proposed in Patent Literatures 2 and 3, a coating film having properties such as antistatic performance can be formed even on an already installed protective cover for a solar panel without a need for special facilities or the like. However, it cannot necessarily be said that properties including antistatic performance, hydrophilicity, and durability such as wear resistance, and the like of a formed coating film are sufficient, and therefore there has been room for further improvements.

The present invention has been completed in view of such problems of conventional techniques, and an object of the present invention is to provide an antistatic coating agent that is excellent in antistatic performance, hydrophilicity, and durability such as wear resistance and that makes it possible to form a coat layer having a high visible light transmittance on a surface of a substrate made of glass easily at normal temperature.

Another object of the present invention is to provide: an antistatic glass substrate including a coat layer that is excellent in antistatic performance, hydrophilicity, and durability such as wear resistance and that has a high visible light transmittance; and a solar panel using this antistatic glass substrate.

### Solution to Problem

That is, according to the present invention, there is provided an antistatic coating agent described below.

[1] A normal-temperature-hardenable antistatic coating agent comprising: tin oxide (SnO₂); silica (SiO₂); tungsten oxide (WO₃); a single-walled carbon nanotube; and a liquid medium.

[2] The antistatic coating agent according to [1], wherein the content of the single-walled carbon nanotube is 0.008 to 0.07% by mass.

[3] The antistatic coating agent according to [1] or [2], wherein the single-walled carbon nanotube has a diameter of 3 nm or smaller.

[4] The antistatic coating agent according to any one of [1] to [3], wherein the liquid medium comprises a water-soluble organic solvent and water.

[5] The antistatic coating agent according to any one of [1] to [4], to be used for forming a coat layer on a surface of a substrate made of glass.

In addition, according to the present invention, there is provided an antistatic glass substrate described below.

[6] An antistatic glass substrate comprising: a substrate made of glass; and a coat layer being a hardened layer provided on a surface of the substrate, the hardened layer formed from the antistatic coating agent according to any one of [1] to [5].

[7] The antistatic glass substrate according to [6], wherein the coat layer has a surface resistance value of 10⁶Ω or less; and a visible light transmittance variation ratio is −0.5% or more as calculated by the following formula (1):

R={(T−T_{B})/T_{B}}×100 (1)

wherein R represents the visible light transmittance variation ratio (%), T_{B} represents visible light transmittance (%) of the substrate, and T represents visible light transmittance (%) of the antistatic glass substrate.

[8] The antistatic glass substrate according to [6] or [7], being a protective cover for a solar panel.

Further, according to the present invention, there is provided a solar panel described below.

[9] A solar panel comprising the antistatic glass substrate according to [8] as a protective cover.

### Advantageous Effects of Invention

The present invention can provide an antistatic coating agent that is excellent in antistatic performance, hydrophilicity, and durability such as wear resistance and that makes it possible to form a coat layer having a high visible light transmittance on a surface of a substrate made of glass easily at normal temperature.

Further, the present invention can provide: an antistatic glass substrate including a coat layer that is excellent in antistatic performance, hydrophilicity, and durability such as wear resistance and that has a high visible light transmittance; and a solar panel using this antistatic glass substrate.

### DESCRIPTION OF EMBODIMENTS

### <Antistatic Coating Agent>

Hereinafter, embodiments of the present invention will be described, but the present invention is not limited to the following embodiments. Various physical property values herein are values at normal temperature (25° C.) and a humidity of 50% RH unless otherwise noted.

One embodiment of an antistatic coating agent (hereinafter, also simply referred to as “coating agent”) of the present invention is a normal-temperature-hardenable coating agent and contains tin oxide (SnO₂), silica (SiO₂), tungsten oxide (WOs), a single-walled carbon nanotube, and a liquid medium. Hereinafter, details on the coating agent of the present embodiment will be described.

Tin oxide (SnO₂) is a component that mainly functions as an antistatic material. Silica (SiO₂) is a component that mainly functions as a low-refractive-index material, a hydrophilic material, and a binder. Tungsten oxide (WO₃) is a component that mainly functions as a photocatalyst. The single-walled carbon nanotube (hereinafter, also referred to as “SWCNT”) is a component that mainly functions as an antistatic material. In addition, the SWCNT has a high thermal conductivity and is therefore a component that makes it possible to improve thermal conductivity of a coat layer to be formed, and accordingly a thaw acceleration effect can also be expected.

When the SWCNT is contained in a general coat agent for glass, there is a tendency that visible light transmittance of a substrate made of glass coated with this coat agent is significantly lowered. On the other hand, the coating agent of the present embodiment contains tungsten oxide (WO₃) together with the SWCNT. When tungsten oxide (WO₃) is contained together with the SWCNT, the visible light transmittance of the coated substrate made of glass is not substantially lowered, or can preferably be improved, and this is different from a coating agent in which tungsten oxide (WO₃) is not contained and only the SWCNT is contained.

As described above, since tin oxide (SnO₂) is a component that also functions as an antistatic material, even a coat agent in which tin oxide (SnO₂) is contained but the SWCNT is not contained exhibits electrical conductivity to some extent and makes it possible to form a coat layer that exhibits antistatic performance. However, electrical conductivity due to tin oxide (SnO₂) depends on humidity, and sufficient electrical conductivity is not exhibited under a low-humidity environment (such as, for example, a desert), which makes antistatic performance insufficient. In contrast, the coating agent of the present embodiment exhibits electrical conductivity by use of the SWCNT and therefore makes it possible to form a coat layer that exhibits antistatic performance. Electrical conductivity due to the SWCNT is considered to be exhibited by electrically conductive paths formed by entanglement of the SWCNT and therefore does not depend on humidity. For this reason, according to the coating agent of the present embodiment, which contains the SWCNT, sufficient electrical conductivity is exhibited even under a low-humidity environment, such as a desert, irrespective of humidity, so that a coat layer that exhibits favorable antistatic performance can be formed.

### (Tin Oxide (SnO₂))

Tin oxide is usually contained in a state of dispersed fine particles in the coating agent. The average particle size of tin oxide is preferably 10 nm or smaller, more preferably 5 nm or smaller. By using fine tin oxide particles having a small average particle size, an influence on visible light transmittance is made small, so that a coating agent that makes it possible to produce a glass substrate having a higher visible light transmittance can be prepared. Note that the “average particle size” herein means a 50% particle size (median size (D₅₀)) in a particle size distribution based on volume.

The content of tin oxide in the coating agent may appropriately be set according to the application of the coating agent, and the like. The content of tin oxide in the coating agent is usually 0.05 to 0.3% by mass, preferably 0.1 to 0.2% by mass.

### (Silica (SiO₂))

A low-refractive-index material is a material that increases visible light transmittance of glass by suppressing surface reflection. Silica which is used as a low-refractive-index material is usually contained in a state of dispersed fine particles in the coating agent. The average particle size of silica is preferably 10 nm or smaller. By using fine silica particles having an average particle size of 10 nm or smaller, a coating agent that makes it possible to produce a glass substate having a higher visible light transmittance can be prepared.

Silica which is used as a hydrophilic material is usually contained in a state of dispersed fine particles in the coating agent. The smaller the particle size of silica, the smaller the contact angle of a coat layer to be formed to water and the higher the hydrophilicity of the coat layer. Therefore, the coating agent of the present embodiment preferably further contains silica having a smaller particle size than the above-described silica which is used as a low-refractive-index material. Specifically, the coating agent of the present embodiment preferably further contains amorphous silica having an average particle size of 2 nm or smaller.

The content of silica (the total content of silica which is used as a low-refractive-index material and amorphous silica) in the coating agent may appropriately be set according to the application of the coating agent, and the like. The content of silica in the coating agent is usually 0.5 to 3% by mass, preferably 1 to 2% by mass.

### (Tungsten Oxide (WO₃))

Tungsten oxide is usually contained in a state of dispersed fine particles in the coating agent. The average particle size of tungsten oxide is preferably 50 nm or smaller, more preferably 40 nm or smaller.

The content of tungsten oxide in the coating agent may appropriately be set according to the application of the coating agent, and the like. The content of tungsten oxide in the coating agent is usually 0.1 to 0.5% by mass, preferably 0.2 to 0.3% by mass.

### (Single-Walled Carbon Nanotube)

The single-walled carbon nanotube (SWCNT) is contained in a dispersed state in the coating agent. The diameter of the SWCNT is usually 3 nm or smaller, preferably 1 to 2 nm.

The content of the SWCNT in the coating agent is preferably 0.008% by mass to 0.07% by mass, more preferably 0.015 to 0.045% by mass. By setting the content of the SWCNT within the above-described range, a coating agent that makes it possible to produce an antistatic glass substrate can be prepared, the antistatic glass substrate having a lower surface resistance value, having more excellent antistatic performance, and having a visible light transmittance equal to or higher than the visible light transmittance before coating.

### (Liquid Medium)

As the liquid medium, a volatile water-soluble organic solvent and water can be used. By using these liquid media, a normal-temperature-hardenable coating agent that can easily be hardened under a normal temperature condition can be prepared. For example, an alcohol, such as methanol and ethanol, can be used as the volatile water-soluble organic solvent.

### (Preparation of Coating Agent)

The coating agent of the present embodiment can easily be prepared by, for example, mixing the respective components such as tin oxide, silica, tungsten oxide, and the SWCNT, or a dispersion of these components in water, a water-soluble organic solvent, or the like with the liquid medium.

### <Antistatic Glass Substrate and Solar Panel>

By using the above-described coating agent, an antistatic glass substrate suitable, for example, as a protective cover for a solar panel can be produced. Specifically, one embodiment of the antistatic glass substrate of the present invention includes a substrate made of glass and a coat layer being a hardened layer provided on a surface of the substrate, the hardened layer formed from the above-described coating agent. One embodiment of the solar panel of the present invention includes this antistatic glass substrate as a protective cover.

The coat layer provided on the surface of the substrate made of glass is a hardened layer formed from the above-described coating agent, and therefore is excellent in antistatic performance, hydrophilicity, and durability such as wear resistance and has a high visible light transmittance. For example, the surface resistance value of the coat layer is preferably 10⁶Ω or less, more preferably 10⁵Ω or less, particularly preferably 10⁴Ω or less. The visible light transmittance variation ratio of the antistatic glass substrate, calculated from the following formula (1), is preferably −0.5% or more, more preferably −0.2% or more, particularly preferably 0.0% or more. Note that the thickness of the coat layer is usually about 100 to about 200 nm. Therefore, the antistatic glass substrate of the present embodiment is suitable as a protective cover for a solar panel.

R={(T−T_{B})/T_{B}}×100 (1)
R: visible light transmittance variation ratio (%)
T_{B}: visible light transmittance (%) of the substrate
T: visible light transmittance (%) of the antistatic glass substrate

The coating agent of the present embodiment, which is used for forming the coat layer, is a normal-temperature-hardenable coating agent. Therefore, the coat layer that is a hardened layer is formed by applying the coating agent on the surface of the substrate made of glass by a desired method, such as brush coating or spraying, and then drying the coating agent under a normal temperature (25° C.) condition, and thus the intended antistatic glass substrate can be obtained. By using the above-described coating agent in this way, a coat layer that exhibits excellent properties including antistatic performance can be formed by only applying the coating agent and drying the coating agent at normal temperature without a need for special facilities or the like, and therefore construction work can easily be performed even to a surface of a protective cover made of glass to be installed on an already installed solar panel.

The antistatic glass substrate of the present embodiment, which is used as a protective panel for a solar panel, has a low surface resistance value and is excellent in antistatic performance, and therefore dirt, such as dust, is unlikely to adhere thereto, or even if the dirt adheres thereto, it is easy to remove the dirt. In addition, the surface of the antistatic glass substrate is highly hydrophilic, and therefore dirt which has adhered is easily washed away by rainwater or the like. Further, the visible light transmittance tends to be rather increased while the antistatic glass substrate includes the coat layer formed from the coating agent containing the SWCNT that contributes to an improvement in antistatic performance, and therefore the coat layer is unlikely to inhibit the power generation efficiency of solar cells (cells). Then, the antistatic glass substrate includes the coat layer formed from the coating agent containing the SWCNT having a high thermal conductivity, and therefore even when the antistatic glass substrate is installed in a cold district or the like where snow accumulation is expected, a thaw acceleration effect can be expected.

### EXAMPLES

Hereinafter, the present invention will be described specifically based on Examples, but the present invention is not limited to these Examples. Note that “parts” and “%” in Examples and Comparative Examples are on a mass basis unless otherwise noted.

### <Materials>

The following materials were provided.
Aqueous dispersion of tin oxide (SnO₂) (manufactured by Sketch Co., Ltd., content of SnO₂: 48, average particle size of SnO₂: 2 nm).
Methanol dispersion of silica (SiO₂) (manufactured by Sketch Co., Ltd., content of SiO₂: 20%, average particle size of SiO₂:10 nm or smaller).
Aqueous dispersion of amorphous silica (SiO₂) (manufactured by Sketch Co., Ltd., content of SiO₂:1.6%, average particle size of SiO₂:2 nm or smaller).
Aqueous dispersion of tungsten oxide (WO₃) (content of WO₃: 5%, average particle size of WO₃: 40 nm).
Single-walled carbon nanotube (SWCNT) (diameter: 1 to 2 nm)

### <Preparation of Coating Agent>

### Examples 1 to 5 and Comparative Examples 1 to 3

Each coating agent was prepared by mixing the aqueous dispersion of tin oxide, the methanol dispersion of silica, the aqueous dispersion of amorphous silica, the aqueous dispersion of tungsten oxide, the SWCNT, and methanol so as to make the composition (%) as shown in Table 1.

### <Production of Antistatic Glass Substrate>

Each coating agent prepared was separately applied on float glass (normal glass, thickness: 3 mm) having a thickness of 3 mm such that the amount of coating agent applied was 10 mb/m², and was left to stand at normal temperature (25° C.) for 30 minutes. Thereby, each coating agent applied was hardened to form a coat layer, and thus an antistatic glass substrate was obtained. The thickness of each coat layer formed was within a range of 150 to 200 nm. Note that float glass on which a coating agent was not applied (a coat layer was not formed) was provided as Reference Example 1.

### <Evaluation>

### (Surface Resistance Value)

The surface resistance value of the surface of each coat layer of the antistatic glass substrates produced was measured using a surface resistance meter (trade name “Digital Surface Resistance Tester TR-SR100,” manufactured by Pepaless Co., Ltd.). The results are shown in Table 1.

### (Visible Light Transmittance)

Visible light transmittance of each antistatic glass substrate produced was measured using a transmission meter (trade name “Spectrum Transmission Meter LS-183,” manufactured by SHENZHEN LINSHANG TECHNOLOGY CO., LTD.). The results are shown in Table 1.

### (Wear Resistance)

Dry rubbing was performed, in which the surface of each coat layer of the antistatic glass substrates produced was rubbed with a nonwoven fabric back and forth 20 times. The contact angle of the surface of the coat layer before and after the dry rubbing to water was measured using a contact angle meter (trade name “CONTACT ANGLE METER B-100,” manufactured by ASUMI GIKEN, LIMITED) to evaluate wear resistance of the coat layer according to the evaluation criteria shown below. The results are shown in Table 1.
A: Change in the contact angle is 5° or smaller
B: Change in the contact angle is larger than 5° and smaller than 10°
C: Change in the contact angle is larger than 10°

TABLE 1

| | | Reference | | | | | | | | |
|---|---|---|---|---|---|---|---|---|---|---|
| | | Example | Example | | | | | Comparative Example | | |
| | | 1 | 1 | 2 | 3 | 4 | 5 | 1 | 2 | 3 |
| Composition | SnO₂ | — | 0.1 | 0.1 | 0.1 | 0.1 | 0.1 | 0.1 | 0.1 | 0.1 |
| | | | to 0.2 | to 0.2 | to 0.2 | to 0.2 | to 0.2 | to 0.2 | to 0.2 | to 0.2 |
| | SiO₂ | — | 1 | 1 | 1 | 1 | 1 | 1 | 1 | 1 |
| | | | to 2 | to 2 | to 2 | to 2 | to 2 | to 2 | to 2 | to 2 |
| | WO [symbol] | — | 0.2 | 0.2 | 0.2 | 0.2 | 0.2 | — | — | 0.2 |
| | SWCNT | — | 0.01 | 0.02 | 0.03 | 0.04 | 0.05 | — | 0.03 | — |
| | Water | — | 50 | 50 | 50 | 50 | 50 | 50 | 50 | 50 |
| | | | to 54 | to 54 | to 54 | to 54 | to 54 | to 54 | to 54 | to 54 |
| | Methanol | — | 45 | 45 | 45 | 45 | 45 | 45 | 45 | 45 |
| | | | to 49 | to 49 | to 49 | to 49 | to 49 | to 49 | to 49 | to 49 |
| Evaluation | Surface resistance | ∞ | 10 [symbol] | 10 [symbol] | 10 [symbol] | 10 [symbol] | 10 [symbol] | 10 [symbol] | 10 [symbol] | 10 [symbol] |
| | value (Ω) | | | | | | | | | |
| | Visible light | 90.5 | 90.8 | 90.5 | 90.8 | 88.8 | 88.3 | 91.7 | 88.6 | 92.0 |
| | transmittance (%) | | to 91.7 | to 91.3 | to 91.5 | to 89.3 | to 89.1 | to 92.0 | to 88.8 | to 92.2 |
| | Visible light | | 0.3 | 0.0 | 0.3 | −1.7 | −1.4 | 1.3 | −1.9 | 1.5 |
| | transmittance | | to 1.2 | to 0.8 | to 1.0 | to −1.2 | to −2.2 | to 1.7 | to −1.7 | to 1.7 |
| | variation ratio R (%) | | | | | | | | | |
| | Wear resistance | — | B | B | A | A | A | C | A | C |

(Unit in composition: % by mass) [symbol]
indicates data missing or illegible when filed

### INDUSTRIAL APPLICABILITY

The antistatic coating agent of the present invention is useful as a material for forming a coat layer on a surface of a substrate made of glass to be used, for example, as a protective cover for a solar panel.

1. A normal-temperature-hardenable antistatic coating agent comprising:
tin oxide (SnO₂);
silica (SiO₂);
tungsten oxide (WO₃);
a single-walled carbon nanotube; and
a liquid medium.

2. The antistatic coating agent according to claim 1, wherein the content of the single-walled carbon nanotube is 0.008 to 0.07% by mass.

3. The antistatic coating agent according to claim 1, wherein the single-walled carbon nanotube has a diameter of 3 nm or smaller.

4. The antistatic coating agent according to claim 1, wherein the liquid medium comprises a water-soluble organic solvent and water.

5. The antistatic coating agent according to claim 1, to be used for forming a coat layer on a surface of a substrate made of glass.

6. An antistatic glass substrate comprising:
a substrate made of glass; and
a coat layer being a hardened layer provided on a surface of the substrate, the hardened layer formed from the antistatic coating agent according to claim 5.

7. The antistatic glass substrate according to claim 6, wherein
the coat layer has a surface resistance value of 10⁶Ω or less; and
a visible light transmittance variation ratio is-0.5% or more as calculated by the following formula (1):
R={(T−T_{B})/T_{B}}×100 (1)
wherein R represents the visible light transmittance variation ratio (%), T_{B} represents visible light transmittance (%) of the substrate, and T represents visible light transmittance (%) of the antistatic glass substrate.

8. The antistatic glass substrate according to claim 7, being a protective cover for a solar panel.

9. A solar panel comprising the antistatic glass substrate according to claim 8 as a protective cover.
